(19) United States
(12) Patent Application Publication
(10) Pub. No.: US 2024/0405011 A1
(43) Pub. Date: Dec. 5, 2024

(54) SEMICONDUCTOR INTEGRATED CIRCUIT, SYSTEM ON CHIP AND ELECTRONIC DEVICE TO IMPLEMENT THEM

(71) Applicant: SAMSUNG ELECTRONICS CO., LTD., SUWON-SI (KR)

(72) Inventor: JONG-HYEOK KIM, Suwon-si (KR)

(21) Appl. No.: 18/678,749

(22) Filed: May 30, 2024

(30) Foreign Application Priority Data
Jun. 1, 2023 (KR) 10-2023-0070649

(51) Int. Cl. H01L 27/02; H01L 27/092; H01L 27/105

(52) U.S. Cl. CPC H01L 27/0207; H01L 27/0928; H01L 27/105

(57) ABSTRACT

A semiconductor integrated circuit, a system on chip and an electronic element are provided. The semiconductor integrated circuit includes a semiconductor substrate having a first region, and a second region, a first power rail extending in a first direction on the first region and connected to an impurity region of a first transistor to provide a first voltage, a second power rail extending in the first direction on the first region and connected to the first transistor to provide a second voltage, a third power rail extending in the first direction on the second region and connected to an impurity region of a second transistor to provide the first voltage, a fourth power rail extending in the first direction on the second region and connected to the second transistor to provide a third voltage, and a first conductor connecting the first power rail with the third power rail.

### CROSS-REFERENCE TO RELATED APPLICATION

This application claims priority from Korean Patent Application No. 10-2023-0070649 filed on Jun. 1, 2023 in the Korean Intellectual Property Office and all the benefits accruing therefrom under 35 U.S.C. 119, the contents of which in its entirety are herein incorporated by reference.

### BACKGROUND

### Technical Field

The present disclosure relates to a semiconductor integrated circuit, a system on chip and an electronic device to implement them.

### Description of the Related Art

Electronic devices such as memory devices, integrated circuits, smart phones, or tablet PCs include power rails for providing operating voltages to electronic elements (e.g., transistors, memory cells, flip-flops, etc.) implemented therein. Stable operating voltages should be supplied to the electronic elements for the proper operation of the electronic device. However, when an instantaneous voltage drop occurs, the electronic elements may operate improperly and generate errors.

### BRIEF SUMMARY

Embodiments of the present disclosure relate to a semiconductor integrated circuit in which a voltage drop effect and the degree of integration of a circuit are resolved.

Principles and embodiments of the present disclosure also relate to providing a system on chip in which a voltage drop effect and the degree of integration of a circuit are resolved.

The present disclosure also relates to providing an electronic device in which a voltage drop effect and the degree of integration of a circuit are resolved.

The various embodiments of the present disclosure are not limited to those mentioned above and additional aspects and features of the present disclosure, will be clearly understood by those skilled in the art from the following description and drawings of the present disclosure.

According to an aspect of the present disclosure, there is provided a semiconductor integrated circuit including a semiconductor substrate including a first region, in which a first transistor configured driven by a first voltage and a second voltage is disposed, and a second region, separate from the first region, in which a second transistor configured to be driven by a third voltage different from the first voltage and the second voltage is disposed, a first power rail extending in a first direction on the first region, and directly connected to an impurity region of the first transistor to provide the first voltage, a second power rail extending in the first direction on the first region and directly connected to the impurity region of the first transistor to provide the second voltage, a third power rail extending in the first direction on the second region and directly connected to an impurity region of the second transistor to provide the first voltage, a fourth power rail extending in the first direction on the second region and directly connected to the impurity region of the second transistor to provide the third voltage, and a first conductor electrically and directly connecting the first power rail with the third power rail.

According to an aspect of the present disclosure, there is provided a system on chip comprising a semiconductor substrate including a first standard cell including a first transistor driven by a first voltage and a second voltage, a second standard cell including a second transistor driven by the first voltage and a third voltage, and a third standard cell including a third transistor driven by a fourth voltage and the second voltage, a first power rail directly connected to an impurity region of the first transistor to provide the first voltage, a second power rail directly connected to the impurity region of the first transistor to provide the second voltage, a third power rail directly connected to an impurity region of the second transistor to provide the first voltage, a fourth power rail directly connected to the impurity region of the second transistor to provide the third voltage, a fifth power rail directly connected to an impurity region of the third transistor to provide the fourth voltage, a sixth power rail directly connected to the impurity region of the third transistor to provide the second voltage, a first conductor electrically and directly connecting the first power rail with the third power rail in a first region in which the first standard cell and the second standard cell of the semiconductor substrate are not disposed, and a second conductor electrically and directly connecting the second power rail with the sixth power rail in a second region in which the first standard cell and the third standard cell of the semiconductor substrate are not disposed.

According to an aspect of the present disclosure, there is provided an electronic device including a processor, and a memory configured to store an instruction, wherein, when the instruction is executed by the processor, the instruction causes the processor to provide a semiconductor substrate, which includes a first region and a second region separate from the first region to form a first power rail extending in a first direction, and directly connected to an impurity region of a first transistor to provide a first voltage on the first region, to form a second power rail extending in the first direction, and directly connected to the impurity region of the first transistor to provide a second voltage on the first region, to form a third power rail extending in the first direction and directly connected to an impurity region of a second transistor to provide the first voltage, wherein the third power rail is on the second region, to form a fourth power rail extending in the first direction and directly connected to the impurity region of the second transistor to provide a third voltage different from the second voltage on the second region, to form a first standard cell including the first transistor driven by the first voltage and the second voltage in the first region, to form a second standard cell including the second transistor driven by the first voltage and the third voltage in the second region, and to form a first conductor outside the first region and the second region, so that the first power rail and the third power rail are electrically and directly connected to each other.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary view illustrating a semiconductor integrated circuit according to some embodiments.

FIG. 2 is an exemplary enlarged view illustrating a region I of FIG. 1.

FIG. 3 is an exemplary view illustrating a semiconductor device in which the semiconductor integrated circuit of FIG. 1 is implemented.

FIG. 4 is an exemplary view illustrating a semiconductor integrated circuit according to various embodiments.

FIGS. 5 and 6 are exemplary views illustrating a semiconductor integrated circuit according to various embodiments.

FIGS. 7 and 8 are exemplary views illustrating a semiconductor integrated circuit according to various embodiments.

FIGS. 9 and 10 are exemplary views illustrating a semiconductor integrated circuit according to various embodiments.

FIG. 11 is an exemplary view illustrating a system on chip according to various embodiments.

FIG. 12 is an exemplary view illustrating a system on chip according to various embodiments.

FIG. 13 is an exemplary view illustrating a system on chip according to various embodiments.

FIG. 14 is an exemplary view illustrating a system on chip according to various embodiments.

FIG. 15 is an exemplary view illustrating a system on chip according to various embodiments.

FIG. 16 is an exemplary view illustrating a semiconductor system according to various embodiments.

FIG. 17 is an exemplary view illustrating a semiconductor system according to various embodiments.

FIG. 18 is an exemplary view illustrating an electronic device according to various embodiments.

FIG. 19 is a flow chart illustrating an example of a method for designing a semiconductor integrated circuit or a system on chip according to various embodiments when the instruction of FIG. 18 is executed by the processor.

### DETAILED DESCRIPTION

Hereinafter, a semiconductor integrated circuit, a system on chip and an electronic device to implement them according to various embodiments will be described with reference to the accompanying drawings.

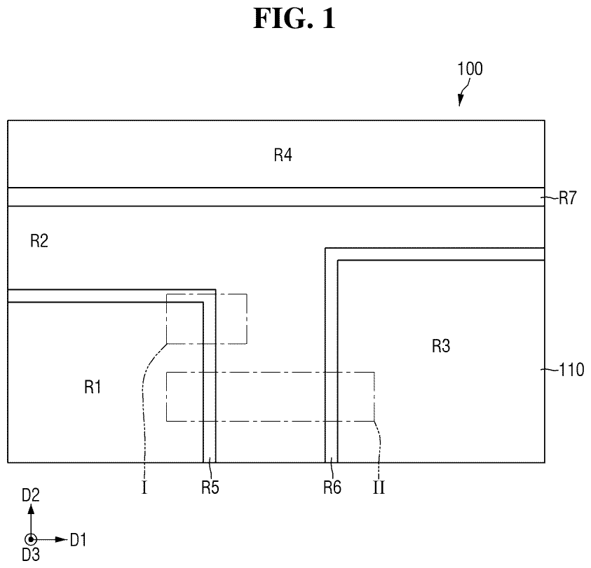

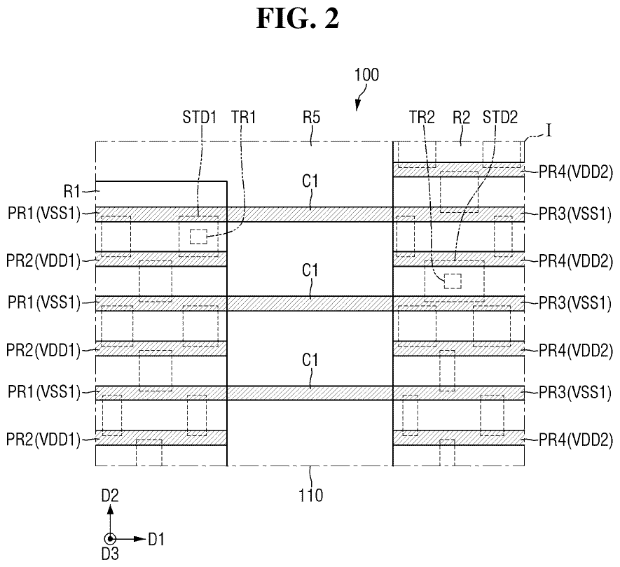

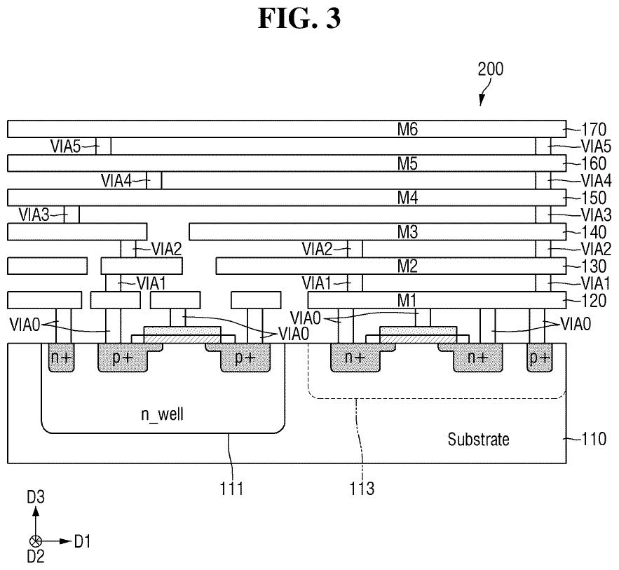

FIG. 1 is an exemplary view illustrating a semiconductor integrated circuit according to some embodiments. FIG. 2 is an exemplary enlarged view illustrating a region I of FIG. 1. FIG. 3 is an exemplary view illustrating a semiconductor device in which the semiconductor integrated circuit of FIG. 1 is implemented. Hereinafter, the semiconductor integrated circuit will be described with reference to FIGS. 1 to 3.

FIGS. 1 and 2 are plan views illustrating a semiconductor integrated circuit 100. Referring to FIG. 1, a semiconductor substrate 110 of the semiconductor integrated circuit 100 may include a plurality of regions R1, R2, R3, R4, R5, R6 and R7. FIG. 1 illustrates a portion of the semiconductor substrate 110, where the semiconductor substrate 110 may further include regions other than the regions R1 to R7. The semiconductor substrate 110 can be a silicon substrate, which may be implemented as a P-type substrate or an N-type substrate in accordance with various embodiments.

In various embodiments, the regions R1, R2, R3 and R4 of the semiconductor substrate 110 may each include one or more electronic elements, respectively. The electronic element included in each of the regions R1, R2, R3 and R4 of the semiconductor substrate 110 may be driven by a high voltage VDD and a low voltage VSS. For example, referring to FIG. 2, the electronic element included in the region R1 may be driven by a high voltage VDD1 and a low voltage VSS1. In addition, the electronic element included in the region R2 may be driven by a high voltage VDD2 and the low voltage VSS1. A magnitude of the low voltage VSS may be smaller than that of the high voltage VDD, where for example, in the region R1, a magnitude of the low voltage VSS1 may be smaller than the magnitude of the high voltage VDD1, and in the region R2, the magnitude of the low voltage VSS1 may be smaller than that of the high voltage VDD2. The second voltage may be a voltage having a magnitude smaller than that of the first voltage, and the third voltage may be a voltage having a magnitude smaller than that of the first voltage.

In various embodiments, the high voltage VDD may be a power voltage, and the low voltage VSS may be a ground voltage. For example, in the region R1, the high voltage VDD1 may be a power voltage, and the low voltage VSS1 may be a ground voltage. In addition, in the region R2, the high voltage VDD2 may be, for example, a power voltage, and the low voltage VSS1 may be a ground voltage. In various embodiments, the low voltage VSS may have a voltage level approximate to a ground voltage of about 0V, rather than a ground voltage of 0V, for example, due to unintended interference or noise.

In various embodiments, the regions R1, R2, R3 and R4 of the semiconductor substrate 110 may be divided based upon the magnitudes of the high voltage VDD and the low voltage VSS, which are applied to the electronic element included in each of the regions. The magnitudes of the high voltage VDD and the low voltage VSS, which are applied to the electronic elements included in the same region, may all be the same as each other. In addition, the magnitudes of the high voltage VDD and the low voltage VSS to the electronic elements included in different regions may be different from each other in at least one of the magnitude of the high voltage VDD or the magnitude of the low voltage VSS.

For example, the magnitude of the high voltage VDD applied to the electronic element included in the region R1 may be equal to that of the high voltage VDD applied to the electronic element included in the region R2, and the magnitude of the low voltage VSS applied to the electronic element included in the region R1 may be different from that of the low voltage VSS applied to the electronic element included in the region R2.

For example, the magnitude of the low voltage VSS applied to the electronic element included in the region R1 and the magnitude of the low voltage VSS applied to the electronic element included in the region R2 should be ideally the ground voltage of 0V, but the magnitude of the low voltage VSS applied to the electronic element included in the region R1 and the magnitude of the low voltage VSS applied to the electronic element included in the region R2 may have their respective voltage levels different from each other and approximate to the ground voltage of 0V due to unintended interference or noise.

In various embodiments, the magnitude of the high voltage VDD applied to the electronic element included in the region R1 may be different from that of the high voltage VDD applied to the electronic element included in the region R2, and the magnitude of the low voltage VSS applied to the electronic element included in the region R1 may be the same as that of the low voltage VSS applied to the electronic element included in the region R2. For example, both the magnitude of the low voltage VSS applied to the electronic element included in the region R1 and the magnitude of the low voltage VSS applied to the electronic element included in the region R2 may be the same as the ground voltage of 0V, whereas the magnitude of the high voltage VDD applied to the electronic element included in the region R1 may be greater or less than the magnitude of the high voltage VDD applied to the electronic element included in the region R2.

In this way, the electronic elements driven by the high voltage VDD and the low voltage VSS may be disposed in each of the regions R1, R2, R3 and R4. For example, a standard cell may be disposed in each of the regions R1, R2, R3 and R4. The standard cell may refer to a group of a transistor structure and an interconnect structure, which are for providing a Boolean logic function (e.g., AND, OR, NAND, NOR, XOR, XNOR or inverter).

In various embodiments, a region on the semiconductor substrate 110 in which an electronic element is not disposed may be located between regions containing one or more electronic elements. For example, a region R5 without an electronic element may be located between the region R1 and the region R2, and a region R6 in which the electronic element is not disposed may be located between the region R2 and the region R3, in addition, a region R7 in which the electronic element is not disposed may be located between the region R2 and the region R4. In other words, electronic elements such as standard cells may not be disposed in the regions R5, R6 and R7. By having regions R5, R6 and R7 without electronic elements located adjoining the regions R1, R2, R3 and R4, in which the electronic elements are disposed, regions R1, R2, R3 and R4 can be separated from each other and can include electronic elements having a difference in at least one of the high voltage VDD or the low voltage VSS, respectively.

Referring to FIG. 2, the semiconductor integrated circuit 100 may include a power rail PR1, a power rail PR2, a power rail PR3, a power rail PR4 and a conductor C1. The power rails PR1, PR2, PR3 and PR4 and the conductor C1 may be disposed on the semiconductor substrate 110. The power rails PR1, PR2, PR3 and PR4 and the conductor C1 may be spaced apart from each other in a third direction D3 from a plane (e.g., a plane defined by a first direction D1 and a second direction D2) on which the semiconductor substrate 110 is disposed.

In various embodiments, a rail may be an electrically conductive material, such as a trace, a strap, a wire or other electrically conductive path, that transmits a voltage (e.g., the high voltage VDD or the low voltage VSS), where for example, the conductive material may be implemented as metal, Cu, Ag, Au, Al or W, but is not limited thereto.

In various embodiments, the power rail PR1 and the power rail PR2 may extended in the first direction D1 on the region R1 of the semiconductor substrate 110. The power rail PR1 and the power rail PR2 may be spaced apart from each other by a predetermined distance or repeating interval in the second direction D2. The power rail PR1 and the power rail PR2 may be provided as a plurality of power rails PR1 and a plurality of power rails PR2, respectively, where each of the plurality of power rails PR1 and each of the plurality of power rails PR2 may be alternately disposed to be spaced apart from each other as much as a predetermined interval in the second direction D2. The second direction D2 may be the direction crossing or intersecting with the first direction D1. For example, the second direction D2 may be the direction perpendicular to the first direction D1.

In various embodiments, a standard cell STD1 may be disposed between the power rail PR1 and the power rail PR2. The standard cell STD1 may include a transistor TR1, and may further include other electronic elements in addition to the transistor TR1, as shown in FIG. 2. The power rail PR1 may transmit the low voltage VSS1 to the standard cell STD1, and the power rail PR2 may transmit the high voltage VDD1 to the standard cell STD1, where the power rails PR1 and PR2 can be electrically connected to the standard cell STD1 and the transistor TR1. Therefore, the electronic elements included in the standard cell STD1 may operate using the high voltage VDD1 and the low voltage VSS1, where for example, the transistor TR1 may be driven by the high voltage VDD1 and the low voltage VSS1. The high voltage VDD1 may be higher than the low voltage VSS1.

In various embodiments, the power rail PR3 and the power rail PR4 may extended in the first direction D1 on the region R2 of the semiconductor substrate 110. The power rail PR3 and the power rail PR4 may be spaced apart from each other by a predetermined distance or repeating interval in the second direction D2. The power rail PR3 and the power rail PR4 may be provided as a plurality of power rails PR3 and a plurality of power rails PR3, respectively, where each of the plurality of power rails PR3 and each of the plurality of power rails PR4 may be alternately disposed to be spaced apart from each other as much as a predetermined interval in the second direction D2.

In various embodiments, a standard cell STD2 may be disposed between the power rail PR3 and the power rail PR4. The standard cell STD2 may include a transistor TR2, and may further include other electronic elements in addition to the transistor TR2, as shown in FIG. 2. The power rail PR3 may transmit the low voltage VSS1 to the standard cell STD2, and the power rail PR4 may transmit the high voltage VDD2 to the standard cell STD2, where the power rails PR3 and PR4 can be electrically connected to the standard cell STD2 and the transistor TR2. Therefore, the electronic elements included in the standard cell STD2 may operate using the high voltage VDD2 and the low voltage VSS1, where for example, the transistor TR2 may be driven by the high voltage VDD2 and the low voltage VSS1.

In various embodiments, the power rail PR1 may be disposed to be aligned with the power rail PR3 in the first direction D1, and the power rail PR2 may be disposed to be aligned with the power rail PR4 in the first direction D1.

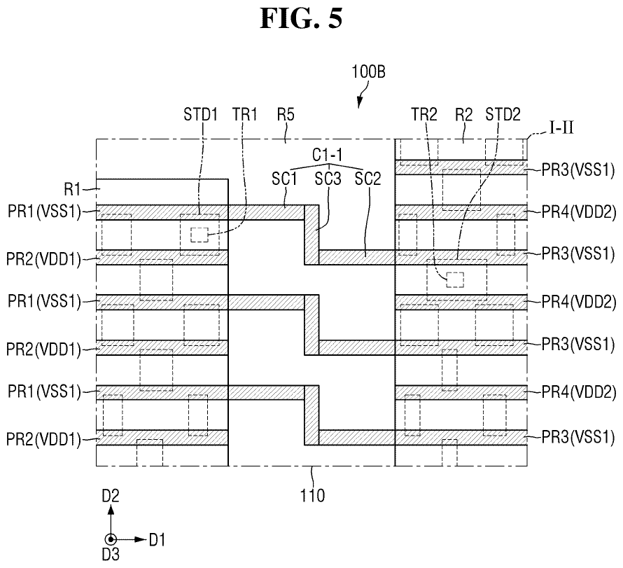

In various embodiments, the conductor C1 may be disposed outside the region R1, in which the power rails PR1 and PR2 and the standard cell STD1 are disposed, and the region R2 in which the power rails PR3 and PR4 and the standard cell STD2 are disposed. The conductor C1 may be disposed on the semiconductor substrate 110 in the region R5 between the region R1 and the region R2. The conductor C1 may electrically connect the power rail PR1 with the power rail PR3, which transmits the same low voltage VSS1. For example, the low voltage VSS1 may be a ground voltage of 0V. The conductor C1 electrically and directly connected to the power rail PR1 and the power rail PR3 will be described later with reference to FIGS. 5 to 10. The conductor C1 may be implemented as a metal, Cu, Ag, Au, Al or W, but is not limited thereto.

In various embodiments, the conductor C1 may be disposed at the same level as the power rail PR1 and the power rail PR3 to electrically connect the power rail PR1 with the power rail PR3. The same level is described below with reference to FIG. 3.

In various embodiments, the power rail PR1 and the power rail PR3, which transmit the same low voltage VSS1, may be electrically connected to each other using the conductor C1, whereby a voltage drop between regions R1 and R2 may be avoided. In addition, the conductor C1 may be disposed in the region R5 in which the electronic element including the standard cell is not disposed, so as to electrically connect the power rail PR1 and the power rail PR3, which transmit the same low voltage VSS1, with each other, thereby improving the degree of integration of the semiconductor integrated circuit 100.

FIG. 3 is a cross-sectional view illustrating a semiconductor device 200 in which the semiconductor integrated circuit 100 is implemented. The semiconductor device 200 may include a semiconductor substrate 110 and a plurality of metal layers 120, 130, 140, 150, 160 and 170 formed on the semiconductor substrate 110, where the plurality of metal layers 120, 130, 140, 150, 160 and 170 can be stacked on the semiconductor substrate 110. The plurality of metal layers 120, 130, 140, 150, 160 and 170 may be spaced apart from one another at a predetermined interval along the third direction D3, but is not limited thereto. Although six metal layers 120, 130, 140, 150, 160 and 170 are shown in FIG. 3, the number of metal layers included in the semiconductor device 200 may be varied depending on the embodiment. For example, the semiconductor device 200 may include more or less than the six metal layers illustrated.

As shown in FIG. 3, some metal layers (for example, metal layers 120, 130, 140) closer to the semiconductor substrate 110 among the plurality of metal layers 120, 130, 140, 150, 160 and 170 in the semiconductor device 200 may be discontinuous along the first direction D1 and partially disconnected from themselves. Some upper metal layers (for example, metal layers 150, 160, 170) farther from the semiconductor substrate 110 in the third direction D3 may be continuous as one layer without being disconnected from themselves. In this way, the metal layers 120, 130, 140, 150, 160 and 170 formed on the semiconductor substrate 110 may be divided into lower metal layers or upper metal layers depending on whether the metal layers are partially disconnected from themselves or connected as one layer. For example, the metal layers 120, 130, 140 which are discontinuous as one layer along the first direction D1 and partially disconnected from themselves may be referred to lower metal layers and the metal layers 150, 160, 170 which are continuous as one layer along the first direction D1 may be referred to upper metal layers.

Although FIG. 3 shows that the metal layers M1 to M3 are discontinuous and the metal layers M4 to M6 are continuous along the first direction D1, the present disclosure is not limited thereto. For example, the metal layers M1 and M2 may be implemented to be partially discontinuous, and the metal layers M3 to M6 may be implemented to be continuous, therefore, the metal layers M1 to M3 may be included in and referred to as the lower metal layers, and the metal layers M4 to M6 may be included in and referred to as the upper metal layers and connected to one layer.

In various embodiments, the semiconductor device 200 may include a plurality of vias VIA0, VIA1, VIA2, VIA3, VIA4 and VIA5, where for example, the vias VIA1 may connect the metal layer M1 with the metal layer M2, the vias VIA2 may connect the metal layer M2 with the metal layer M3, the vias VIA3 may connect the metal layer M3 with the metal layer M4, the vias VIA4 may connect the metal layer M4 with the metal layer M5, and the vias VIA5 may connect the metal layer M5 with the metal layer M6. The vias VIA0 may connect impurity regions in the substrate 110 with the metal layer M1, and may connect a gate (or gate electrode) of a transistor with the metal layer M1.

Active regions 111 and 113 may be formed in the semiconductor substrate 110. Each of the active regions 111 and 113 may include impurity regions (e.g., p+ and/or n+), and at least one transistor may be defined by the impurity regions. The impurity regions may include a drain region and a source region. For example, the impurity regions may include a p+ region and/or an n+ region. The semiconductor device 200 may further include a gate of a transistor, a polysilicon layer, and metal contacts.

In various embodiments, the transistor TR1 included in the region R1 and the transistor TR2 included in the region R2, which are shown in FIG. 2, may be included in the transistor defined by the impurity regions (p+ and/or n+) included in each of the active regions 111 and 113.

In addition, the power rails PR1, PR2, PR3 and PR4 shown in FIG. 2 may be formed in the lower metal layer of the metal layers 120, 130, 140, 150, 160 and 170. The power rails PR1, PR2, PR3 and PR4 may be formed in the lower metal layers in which some of the metal layers 120, 130, 140, 150, 160 and 170 are discontinuous. For example, the power rails PR1, PR2, PR3 and PR4 may be formed in one of the metal layers M1 to M3.

In various embodiments, the power rail PR1 may be directly connected electrically to the impurity region (p+ or n+) of the transistor TR1 to provide the high voltage VDD1 to the transistor TR1. In addition, the power rail PR2 may be directly connected electrically to the impurity region (p+ or n+) of the transistor TR1 to provide the low voltage VSS1 to the transistor TR1. For example, when the power rail PR1 and the power rail PR2 are formed in the metal layer M1, each of the power rail PR1 and the power rail PR2 may be directly connected to the impurity region (p+ or n+) of the transistor TR1 through the via VIA to provide the high voltage VDD1 and the low voltage VSS1.

In another embodiment, the power rail PR1 and the power rail PR2 can be formed in the metal layer M2, where the power rail PR1 and the power rail PR2 may be directly connected electrically to the impurity region (p+ or n+) of the transistor TR1 through the via VIA1, the metal layer M1 and the via VIA0, respectively, to provide the high voltage VDD1 and the low voltage VSS1.

In still another embodiment, when the power rail PR1 and the power rail PR2 are formed in the metal layer M3, the power rail PR1 and the power rail PR2 may be directly connected to the impurity region (p+ or n+) of the transistor TR1 through the via VIA2, the metal layer M2, the via VIA1, the metal layer M1 and the via VIA0 to provide the high voltage VDD1 and the low voltage VSS1.

In various embodiments, the power rail PR3 may be directly connected electrically to the impurity region (p+ or n+) of the transistor TR2 to provide the high voltage VDD2 to the transistor TR2. The power rail PR4 may be directly connected to the impurity region (p+ or n+) of the transistor TR2 to provide the low voltage VSS1 to the transistor TR2. For example, when the power rail PR3 and the power rail PR4 are formed in the metal layer M1, each of the power rail PR3 and the power rail PR4 may be directly connected electrically to the impurity region (p+ or n+) of the transistor TR2 through the via VIA0 to provide the high voltage VDD2 and the low voltage VSS1. Even though the power rail PR3 and the power rail PR4 are formed in the metal layer M2 or the metal layer M3, as described above with respect to the power rail PR1 and the power rail PR2, the power rail PR3 and the power rail PR4 may be directly connected electrically to the impurity region (p+ or n+) of the transistor TR2 to provide the high voltage VDD2 and the low voltage VSS1 to the transistor TR2.

In various embodiments, the conductor C1 may be disposed at the same level as the power rail PR1 and the power rail PR3 to electrically connect the power rail PR1 with the power rail PR3. The same level may mean that the level of the metal layer in which the conductor C1 is disposed is the same as the level of the metal layer in which the power rail PR1 and the power rail PR3 are disposed. For example, when the power rail PR1 and the power rail PR3 are formed in the metal layer M1, the conductor C1 may also be formed in the metal layer M1 and be disposed at the same level in the third direction D3 from the semiconductor substrate 110 as the power rail PR1 and the power rail PR3. The conductor C1 can thereby electrically connect power rail PR1 with the power rail PR3 without connecting to other metal layers.

In various embodiments, a plurality of impurity regions (e.g., p+ region and n+ region) for forming a hard macro may be formed in each of the active regions 111 and 113. The hard macro may include a memory cell. The plurality of impurity regions (e.g., p+ region and n+ region) formed in the active regions 111 and 113 may be intended to form a volatile memory cell or a nonvolatile memory cell.

In various embodiments, the volatile memory cell may be a random access memory (RAM), a dynamic RAM (DRAM), a static RAM (SRAM), a thyristor RAM (T-RAM), a zero capacitor RAM (Z-RAM) or a twin transistor RAM (TTRAM), but is not limited thereto. The nonvolatile memory cell may be a read only memory (ROM), an electrically erasable programmable ROM (EEPROM), a flash memory, a magnetic RAM (MRAM), a spin-transfer torque MRAM, a ferroelectric RAM (FeRAM), a phase change RAM (PRAM) or a resistive RAM (RRAM), but is not limited thereto.

In various embodiments, the flash memory may be implemented as a NAND-type flash memory or a NOR-type flash memory. For example, the NAND-type flash memory may be included in a smart card, a secure digital (SD) card, a micro SD card, a multimedia card (MMC), an embedded MMC (eMMC), an embedded multi-chip package (eMCP), a perfect page NAND (PPN), a universal flash storage (UFS), a solid state drive (SSD), or an embedded SSD. Therefore, the semiconductor device 200 may mean a semiconductor device that includes a volatile memory cell or a non-volatile memory cell.

In various embodiments, the hard macro may refer to intellectual property (IP), where the IP may mean a functional block that may be used in an integrated circuit (IC), a system on chip (SoC) or an application processor (AP). The IP or the functional block may mean a central processing unit (CPU), a processor, each core included in a multi-core processor, a memory device, a universal serial bus (USB), a peripheral component interconnect (PCI), a digital signal processor (DSP), a wired interface, a wireless interface, a controller, a hardware codec, a video module (e.g., a camera interface, a Joint Photographic Experts Group (JPEG) processor, a video processor, an audio system, a buffer, a driver and the like). In this case, the functional block may mean a circuit or a hardware module, which has unique features.

In various embodiments, the hard macro may also include an analog-to-digital converter ADC and/or a digital-to-analog converter DAC, a logic gate capable of implementing a Boolean function, and/or a standard cell.

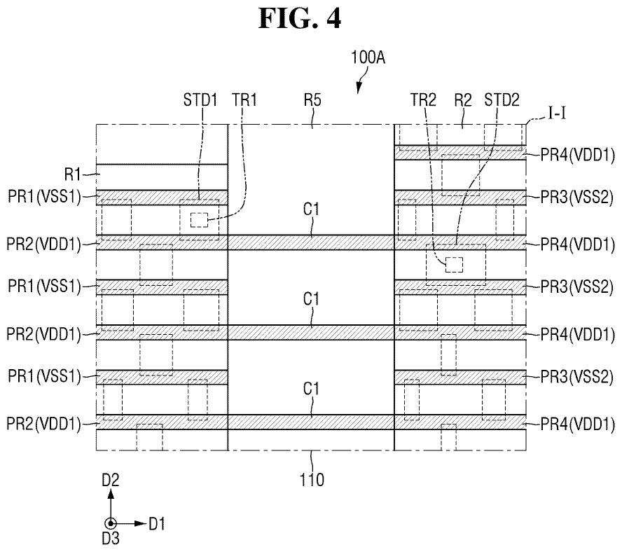

FIG. 4 is an exemplary view illustrating a semiconductor integrated circuit according to various embodiments. Hereinafter, the redundant description of the previous embodiments may be omitted for clarity, and the following description will be based on differences from the previous embodiments.

Referring to FIG. 4, a semiconductor integrated circuit 100A may include a power rail PR1, a power rail PR2, a power rail PR3, a power rail PR4, and a conductor C1.

In various embodiments, the power rail PR1 may transmit a low voltage VSS1 to a standard cell STD1, and the power rail PR2 may transmit a high voltage VDD1 to the standard cell STD1, therefore, electronic elements included in the standard cell STD1 may operate using the high voltage VDD1 and the low voltage VSS1. For example, a transistor TR1 included in the standard cell STD1 may be driven by the high voltage VDD1 and the low voltage VSS1.

In various embodiments, the power rail PR3 may transmit a low voltage VSS2 to a standard cell STD2, and the power rail PR4 may transmit the high voltage VDD1 to the standard cell STD2, therefore, electronic elements included in the standard cell STD2 may operate using the high voltage VDD1 and the low voltage VSS2. For example, the transistor TR2 may be driven by the high voltage VDD1 and the low voltage VSS2.

In various embodiments, the conductor C1 may be disposed on a region R5 between a region R1 and a region R2 on the semiconductor substrate 110, where the conductor C1 can electrically and directly connect the power rail PR2 with the power rail PR4, which transmit the same high voltage VDD1. In various embodiments, the conductor C1 may be disposed at the same level as the power rail PR2 and the power rail PR4 to electrically connect the power rail PR2 with the power rail PR4, where the conductor C1 may be disposed at the same level in the third direction D3 from the semiconductor substrate 110 and a metal layer (e.g., a metal layer M1) in which the power rail PR2 and the power rail PR4 are formed, thereby electrically connecting the power rail PR2 with the power rail PR4.

In various embodiments, the low voltages VSS1 and VSS2 for driving the electronic elements disposed in each of the regions R1, R2 are different from each other, but may have the same high voltage VDD1. For example, although the low voltage VSS1 and the low voltage VSS2 should be a ground voltage of 0V, each of the low voltage VSS1 and the low voltage VSS2 may have a voltage level approximate to the ground voltage of 0V rather than the ground voltage 0V, due to unintended interference or noise, and a magnitude of the low voltage VSS1 and a magnitude of the low voltage VSS2 may be different from each other.

The power rails PR2 and PR4 for transmitting the same high voltage VDD1 may be electrically connected to each other using the conductor C1, thereby avoiding a voltage drop and improving the degree of integration of the semiconductor integrated circuit 100.

Hereinafter, the redundant description of the previous embodiments may be omitted in FIGS. 5 to 10, and the following description will be based on differences from FIGS. 5 to 10. In addition, a case that the same low voltage VSS1 is applied between the region R1 and the region R2 (for example, the case that the low voltage VSS1 is the ground voltage of 0V) and a case that the high voltages VDD1 and VDD2 are different from each other will be described as examples. However, as shown in FIG. 4, the description of the embodiments may be applied to the case that the same high voltage VDD1 is applied between the region R1 and the region R2 and the low voltages VSS1 and VSS2 are different from each other.

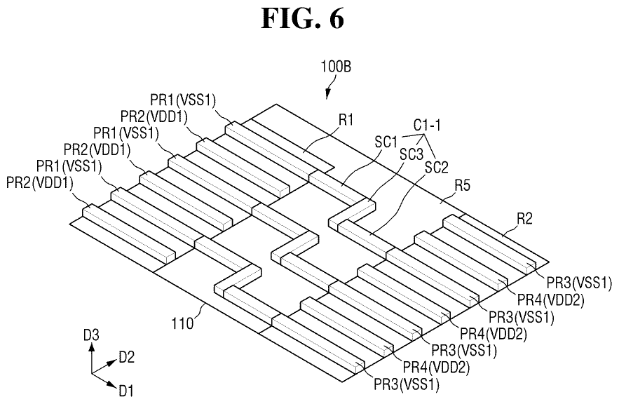

FIGS. 5 and 6 are exemplary views illustrating a semiconductor integrated circuit according to various embodiments.

Referring to FIGS. 5 and 6, the semiconductor integrated circuit 100B includes the power rail PR1 for transmitting the low voltage VSS1 and the power rail PR3 for transmitting the low voltage VSS1, where the power rail PR1 and the power rail PR3 are not horizontally aligned in the first direction D1. In addition, the power rail PR1 for transmitting the low voltage VSS1 and the power rail PR4 for transmitting the high voltage VDD2 may be horizontally aligned in the first direction D1.

In various embodiments, the power rail PR1 of the region R1 and the power rail PR3 of the region R2, configured to transmit the same low voltage VSS1, may be electrically and directly connected to each other by a conductor C1-1. The conductor C1-1 may include sub-conductors SC1, SC2 and SC3, where the sub-conductors SC1, SC2 and SC3 form an electrical path. The sub-conductor SC1 may be extended in the first direction D1 and electrically connected to the power rail PR1, and the sub-conductor SC2 may be extended in the first direction D1 and electrically connected to the power rail PR3. In addition, the sub-conductor SC3 may be extended in the second direction D2 crossing or intersecting with the first direction D1, and may electrically connect the sub-conductor SC1 with the sub-conductor SC2 to form a continuous electrical path.

In various embodiments, the sub-conductors SC1, SC2 and SC3 constituting the conductor C1-1 may be disposed on the region R5, in which an electronic element such as a standard cell is not disposed. The sub-conductors SC1, SC2 and SC3 may be disposed at the same level as the power rails PR1 and PR3, as shown in FIG. 6. For example, when the power rails PR1 and PR3 are formed in the metal layer M1, the sub-conductors SC1, SC2, and SC3 may be disposed at the same level in the third direction D3, as the level at which the metal layer M1 is disposed from the semiconductor substrate 110, to electrically connect the power rail PR1 with the power rail PR3. The power rail PR1 and power rail PR3 may not be colinear, such that sub-conductors SC1, SC2, and SC3 form a bend or jog at the same level.

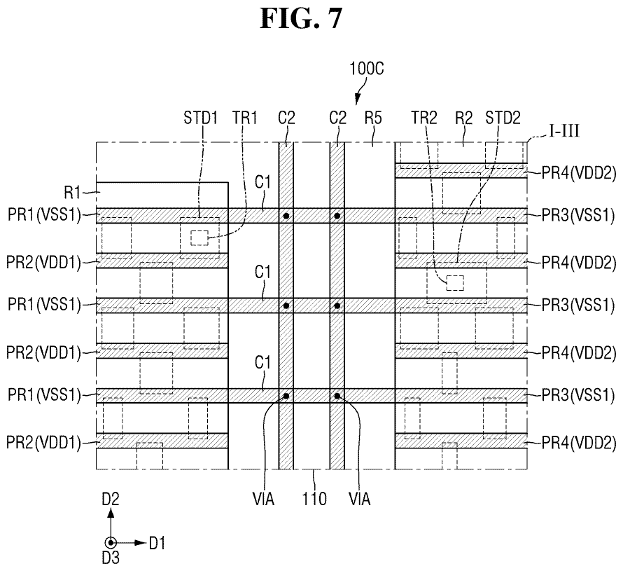

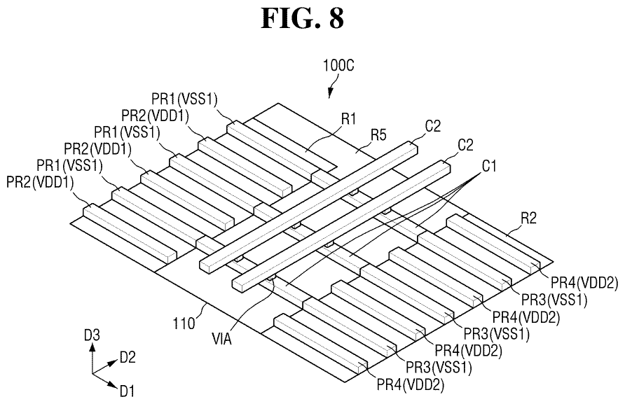

FIGS. 7 and 8 are exemplary views illustrating a semiconductor integrated circuit according to various embodiments.

Referring to FIGS. 7 and 8, a semiconductor integrated circuit 100C may further include a conductor C2 disposed on the region R5, in which the electronic element is not disposed, where conductor C2 is outside the region R1 and the region R2. The conductor C2 may be extended in the second direction D2 crossing or intersecting with the first direction D1, and may be electrically connected to the conductor C1. The conductor C2 may be disposed at a level different from that of the conductor C1. For example, as shown in FIG. 8. When the conductor C1 is disposed at the same level as the power rail PR1 and the power rail PR3, the conductor C2 may be disposed at a higher level in the third direction D3 from the semiconductor substrate 110 than the conductor C1. In various embodiments, when the power rails PR1 and PR3 and the conductor C1 are disposed at a level in which the metal layer M1 is formed in the third direction D3 from the semiconductor substrate 110, the conductor C2 may be disposed at a level at which the metal layer M2 is formed. The conductor C1 and the conductor C2 may be electrically connected to each other through the via VIA, where the via VIA can be located at the intersection of conductor C1 and conductor C2. The via VIA may extend in a direction (e.g., the third direction D3) crossing or intersecting with the plane on which the semiconductor substrate 110 is disposed (e.g., the plane defined by the first direction D1 and the second direction D2).

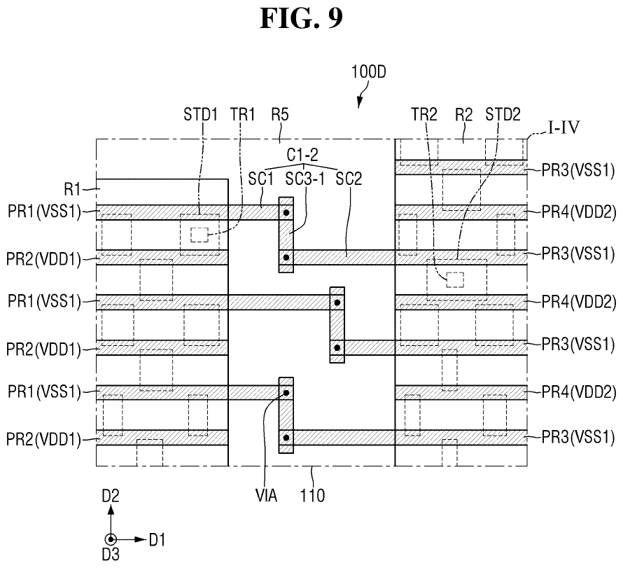

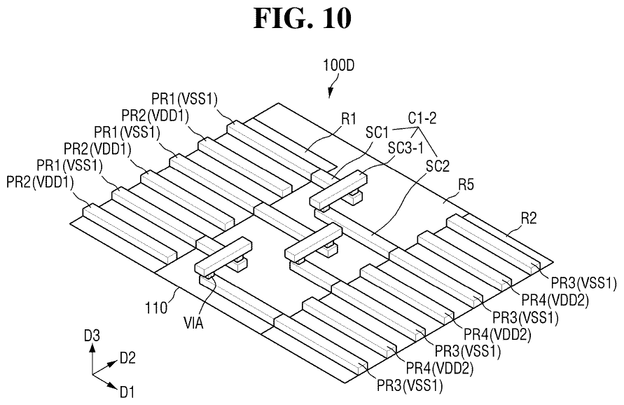

FIGS. 9 and 10 are exemplary views illustrating a semiconductor integrated circuit according to various embodiments.

Referring to FIGS. 9 and 10, in a semiconductor integrated circuit 100D, the power rail PR1 of the region R1 and the power rail PR3 of the region R2, which transmit the same low voltage VSS1, may be electrically and directly connected to each other by a conductor C1-2. The conductor C1-2 may include sub-conductors SC1, SC2 and SC3-1. The sub-conductor SC1 may be extended in the first direction D1 and electrically connected to the power rail PR1, and the sub-conductor SC2 may be extended in the first direction D1 and electrically connected to the power rail PR3. In addition, the sub-conductor SC3-1 may extend in the second direction D2 crossing or intersecting with the first direction D1, and may electrically connect the sub-conductor SC1 with the sub-conductor SC2, where the electrical connection can be through a via VIA.

The sub-conductors SC1, SC2 and SC3-1 constituting the conductor C1-2 may be disposed on the region R5, in which an electronic element such as a standard cell is not disposed, outside the region R1 in which the standard cell STD1 is disposed and the region R2 in which the standard cell STD2 is disposed. In addition, the sub-conductors SC1 and SC2 may be disposed at the same level as the power rails PR1 and PR3. For example, when the power rails PR1 and PR3 are formed in the metal layer M1, the sub-conductors SC1 and SC2 may be disposed at the same level as the level in which the metal layer M1 is disposed in the third direction D3 from the semiconductor substrate 110. In addition, the sub-conductor SC3-1 electrically connecting the sub-conductor SC1 with the sub-conductor SC2 may be disposed at a higher level in the third direction D3 from the semiconductor substrate 110 than the power rails PR1 and PR3 and the sub-conductors SC1 and SC2. In various embodiments, when the power rails PR1 and PR3 and the sub-conductors SC1 and SC2 are disposed at a level in which a metal layer M1 is formed in the third direction D3 from the semiconductor substrate 110, the sub-conductor SC3-1 may be disposed at the level at which the metal layer M2 is formed. The sub-conductor SC3-1 may be electrically connected to the sub-conductors SC1 and SC2 through the via VIA. The via VIA may extend along a direction (e.g., the third direction D3) crossing or intersecting with the plane on which the semiconductor substrate 110 is disposed (e.g., the plane defined by the first direction D1 and the second direction D2).

In various embodiments, the power rail PR1 or PR2 of the region R1 and the power rail PR3 or PR4 of the region R2, which transmit the same high voltage VDD or the same low voltage VSS, can be electrically and directly connected to each other by the conductor, where the conductor may be included in the lower metal layers of the plurality of metal layers 120, 130, 140, 150, 160 and 170. The conductor may be included in the lower metal layers M1, M2 and M3 in which the plurality of metal layers 120, 130, 140, 150, 160 and 170 are partially discontinuous, and may not be included in the upper metal layers M4, M5 and M6.

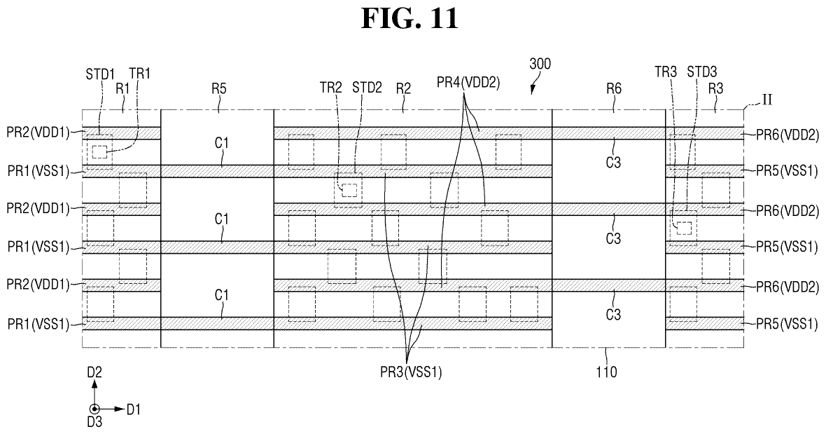

Hereinafter, the redundant description of the previous embodiments may be omitted in FIGS. 11 to 15, and the following description will be based on differences from the previous embodiments.

FIG. 11 is an exemplary view illustrating a system on chip according to various embodiments. FIG. 11 is an exemplary enlarged view illustrating a region II of FIG. 1.

Referring to FIG. 11, a system on chip 300 may include a semiconductor substrate 110, first to sixth power rails PR1 to PR6 and conductors C1 and C3. The regions R1, R2 and R3 on the semiconductor substrate 110 may be disposed to be adjacent to one another. For example, the region R1 may be adjacent to the region R2, and the region R2 may be adjacent to the region R3. At least one of the high voltage VDD or low voltage VSS may be different in regions R1, R2, and/or R3, as applied to the electronic elements included in two regions adjacent to each other. The power rails, which transmit the same high voltage VDD or the same low voltage VSS, among the power rails disposed on two adjacent regions may be electrically connected to each other.

In various embodiments, when the power rail PR1 disposed on the region R1 and the power rail PR3 disposed on the region R2 transmit the same low voltage VSS1, the power rail PR1 and the power rail PR3 may be electrically and directly connected to each other by the conductor C1. The conductor C1 may be disposed on the region R5, in which the standard cell STD1 and the standard cell STD2 are not disposed. In addition, when the power rail PR4 disposed on the region R2 and the power rail PR6 disposed on the region R3 transmit the same high voltage VDD2, the power rail PR4 and the power rail PR6 may be electrically and directly connected to each other by the conductor C3. The conductor C3 may be disposed on the region R6, in which the standard cell STD2 and a standard cell STD3 are not disposed.

In various embodiments, the above descriptions of standard cells STD1 and STD2, the transistors TR1 and TR2, the power rails PR1 to PR4 and the conductor C1 of the region R5 may be applied to the standard cell STD3, the transistor TR3, the power rails PR5, PR6, and the conductor C3 of the region R6.

Although FIG. 11 shows that the power rail PR1 of the region R1 and the power rail PR3 of the region R2, which transmit the same low voltage VSS1, are electrically and directly connected to each other by the conductor C1 and that the power rail PR4 of the region R2 and the power rail PR6 of the region R3, which transmit the same high voltage VDD2, are electrically and directly connected to each other by the conductor C2, the embodiment is not limited thereto. For example, in some embodiments, the power rails for transmitting the same high voltage VDD between the region R1 and the region R2 may be electrically and directly connected to each other by the conductor C1, or the power rails for transmitting the same low voltage VSS between the region R1 and the region R2 may be electrically and directly connected to each other by the conductor C1. Alternatively, when the high voltage VDD or the low voltage VSS is equally applied among the three regions R1, R2 and R3, the power rail of the region R1 and the power rail of the region R2, which transmit the same voltage, may be electrically and directly connected to each other by the conductor C1, and the power rail of the region R2 and the power rail of the region R3, which transmit the same voltage, may be electrically and directly connected to each other by the conductor C3.

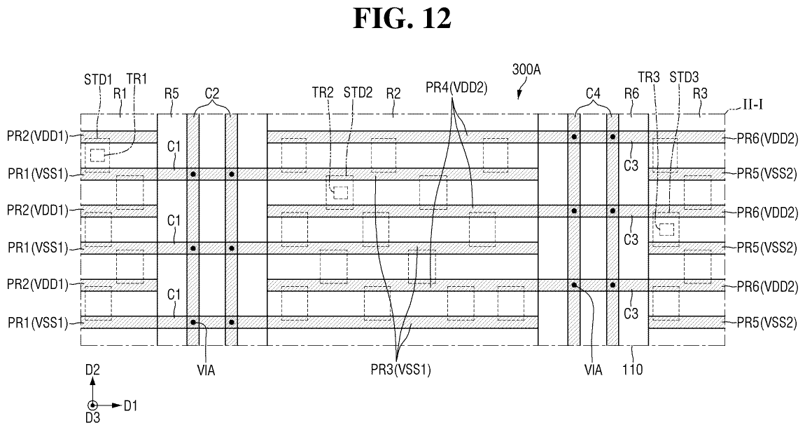

FIG. 12 is an exemplary view illustrating a system on chip according to various embodiments.

Referring to FIG. 12, a system on chip 300A may further include a conductor C4 disposed on the region R6, in which the electronic element is not disposed, where conductor C4 is outside the region R2 and the region R3. The conductor C4 may extend in the second direction D2 crossing or intersecting with the first direction D1, and may be electrically connected to the conductor C3. The conductor C4 may be disposed at a level different from that of the conductor C3. For example, when the conductor C3 is disposed at the same level as that of the power rail PR4 and the power rail PR6, the conductor C4 may be disposed at a higher level in the third direction D3 from the semiconductor substrate 110 than the conductor C3. In various embodiments, when the power rails PR1, PR3, PR4 and PR6 and the conductors C1 and C3 are disposed at the level at which the metal layer M1 is formed in the third direction D3 from the semiconductor substrate 110, the conductor C2 and the conductor C4 may be disposed at the level at which the metal layer M2 is formed. That is, the conductor C2 and the conductor C4 may be disposed at the same level. The conductor C3 and the conductor C4 may be electrically connected to each other through the via VIA. The via VIA may extend in a direction (e.g., the third direction D3) crossing or intersecting with the plane on which the semiconductor substrate 110 is disposed (e.g., the plane defined by the first direction D1 and the second direction D2).

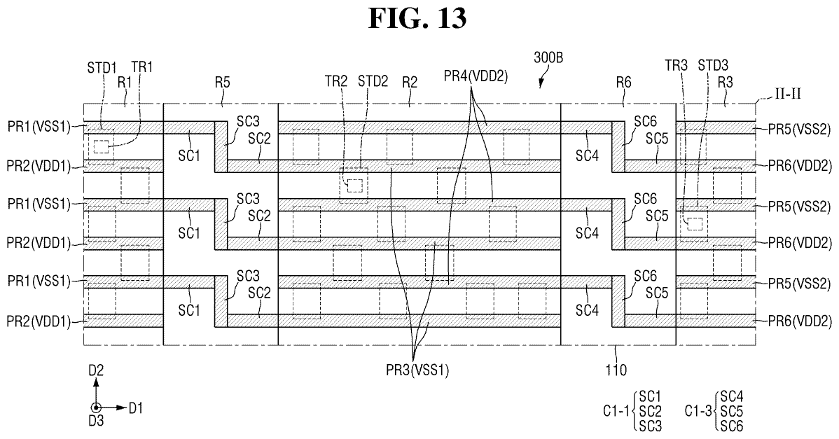

FIG. 13 is an exemplary view illustrating a system on chip according to various embodiments.

Referring to FIG. 13, in a system on chip 300B, the power rail PR4 for transmitting the high voltage VDD2 to the region R2 and the power rail PR6 for transmitting the high voltage VDD2 to the region R3 may not be aligned in the first direction D1. In addition, the power rail PR4 for transmitting the high voltage VDD2 to the region R2 and the power rail PR5 for transmitting the low voltage VSS2 to the region R3 may be aligned in the first direction D1.

In various embodiments, the power rail PR4 of the region R2 and the power rail PR6 of the region R3, which transmit the same high voltage VDD2, may be electrically and directly connected to each other by a conductor C1-3. The conductor C1-3 may include sub-conductors SC4, SC5 and SC6. The sub-conductor SC4 may extend in the first direction D1 and be electrically connected to the power rail PR4, and the sub-conductor SC5 may extend in the first direction D1 and be electrically connected to the power rail PR6. In addition, the sub-conductor SC6 may be extended in the second direction D2 crossing or intersecting with the first direction D1, and may electrically connect the sub-conductor SC4 with the sub-conductor SC5.

In various embodiments, the sub-conductors SC4, SC5 and SC6 constituting the conductor C1-3 may be disposed on the region R6, in which an electronic element such as a standard cell is not disposed, outside the region R2 in which the standard cell STD2 is disposed and the region R3 in which the standard cell STD3 is disposed. The sub-conductors SC4, SC5 and SC6 may be disposed at the same level as the power rails PR4 and PR6. For example, when the power rails PR4 and PR6 are formed in the metal layer M1, the sub-conductors SC4, SC5 and SC6 may be disposed at the same level as the level at which the metal layer M1 is disposed, so as to electrically connect the power rail PR4 with the power rail PR6. In various embodiments, all of the conductors C1-1 and C1-3 and the power rails PR1 to PR6 of the system on chip 300B may be disposed at the same level, where for example, all of the conductors C1-1 and C1-3 and the power rails PR1 to PR6 may be disposed at the level of the metal layer M1.

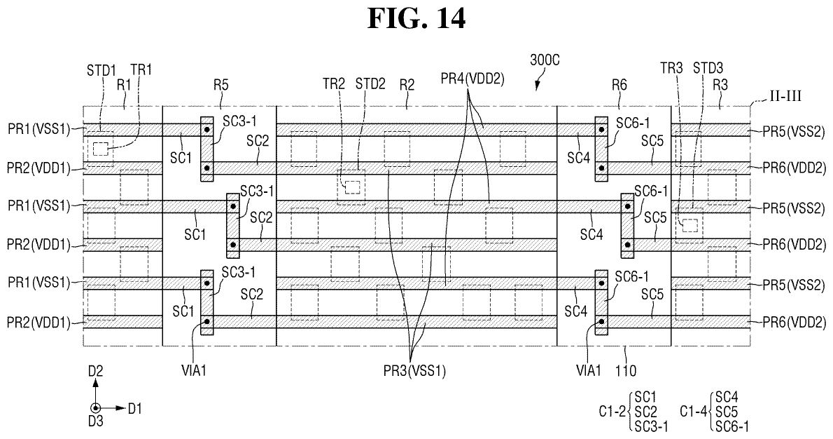

FIG. 14 is an exemplary view illustrating a system on chip according to various embodiments.

Referring to FIG. 14, when the power rail PR4 of the region R2 and the power rail PR6 of the region R3, which transmit the same high voltage VDD2, are not aligned in the first direction D1, the power rail PR4 and the power rail PR6 may be electrically and directly connected to each other by a conductor C1-4 that includes sub-conductors SC4, SC5 and SC6-1. The sub-conductor SC4 may extend in the first direction D1 and be electrically connected to the power rail PR4, and the sub-conductor SC5 may extend in the first direction D1 and be electrically connected to the power rail PR6. The sub-conductor SC6-1 may extend in the second direction D2 crossing or intersecting with the first direction D1, and may electrically connect the sub-conductor SC4 with the sub-conductor SC5.

In various embodiments, the sub-conductors SC4, SC5 and SC6-1 constituting the conductor C1-4 may be disposed on the region R6, in which an electronic element such as a standard cell is not disposed, outside the region R2 in which the standard cell STD2 is disposed and the region R3 in which the standard cell STD3 is disposed. The sub-conductors SC4 and SC5 may be disposed at the same level as the power rails PR4 and PR6. For example, when the power rails PR4 and PR6 are formed in the metal layer M1, the sub-conductors SC4 and SC5 may be at the same level as the metal layer M1, in the third direction D3 from the semiconductor substrate 110.

In various embodiments, the sub-conductor SC6-1 electrically connecting the sub-conductor SC4 with the sub-conductor SC6 may be disposed at a higher level in the third direction D3 from the semiconductor substrate 110 than the power rails PR4 and PR6 and the sub-conductors SC4 and SC5. In various embodiments, when the power rails PR4 and PR6 and the sub-conductors SC4 and SC5 are disposed at the level, at which the metal layer M1 is formed, in the third direction D3 from the semiconductor substrate 110, the sub-conductor SC6-1 may be disposed at the level at which the metal layer M2 is formed. The sub-conductor SC6-1 may be electrically connected to the sub-conductors SC4 and SC5 through the via VIA. The via VIA may extend along a direction (e.g., the third direction D3) crossing or intersecting with the plane on which the semiconductor substrate 110 is disposed (e.g., the plane defined by the first direction D1 and the second direction D2).

In various embodiments, the sub-conductor SC3-1 and the sub-conductor SC6-1 may be disposed at the same level in the third direction D3 from the semiconductor substrate 110. For example, when the power rails PR1 to PR6 are formed in the metal layer M1 and the sub-conductors SC1, SC2, SC4 and SC5 are disposed at the same level as the power rails PR1 to PR6, the sub-conductor SC3-1 and the sub-conductor SC6-1 may be disposed at the level at which the metal layer M2 is disposed, and at a higher level than the metal layer M1 is disposed.

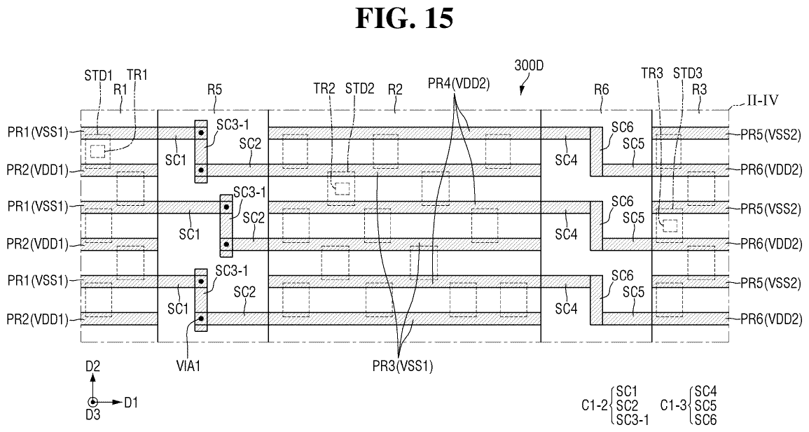

FIG. 15 is an exemplary view illustrating a system on chip according to various embodiments.

Referring to FIG. 15, in a system on chip 300D, the power rails PR1 to PR6 may be formed in metal layers of the same level, where for example, all of the power rails PR1 to PR6 may be formed in the metal layer M1. The power rail PR1 of the region R1 and the power rail PR3 of the region R2, which transmit the same low voltage VSS1, may be electrically and directly connected to each other by the sub-conductors SC1 and SC2 disposed at the same level as the power rails PR1 and PR3, and the sub-conductor SC3-1 can be disposed at a higher level than the power rails PR1 and PR3 and the sub-conductors SC1 and SC2. For example, when the power rails PR1 and PR3 and the sub-conductors SC1 and SC2 are formed in the metal layer M1, the sub-conductor SC3-1 may be disposed at the level at which the metal layer M2 is formed.

In various embodiments, the power rail PR4 of the region R2 and the power rail PR6 of the region R3, which transmit the same high voltage VDD2, may be electrically and directly connected to each other by the sub-conductors SC4, SC5 and SC6 disposed at the same level as the power rails PR4 and PR6.

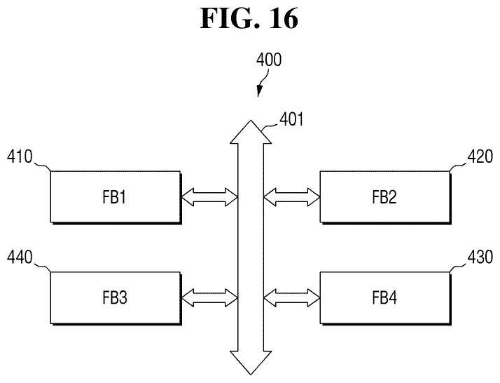

FIG. 16 is an exemplary view illustrating a semiconductor system according to various embodiments.

Referring to FIG. 16, a semiconductor system 400 may include a bus 401 and a plurality of functional blocks FB1, FB2, FB3 and FB4. The semiconductor system 400 may be implemented as a system on chip, for example. The semiconductor system 400 may include a structure of the semiconductor integrated circuit described with reference to FIGS. 1 to 10 or a structure of the system on chip described with reference to FIGS. 11 to 15.

In various embodiments, the semiconductor system 400 may include a structure in which power rails for transferring the same voltage are electrically and directly connected to each other by a conductor when one of the high voltage VDD and/or the low voltage VSS is equally applied between two adjacent functional blocks among the functional blocks FB1 to FB4.

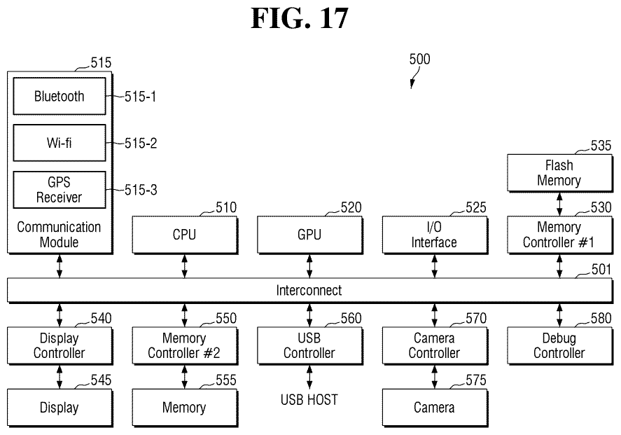

FIG. 17 is an exemplary view illustrating a semiconductor system according to various embodiments.

Referring to FIG. 17, a semiconductor system 500 may include a structure of the semiconductor integrated circuit described with reference to FIGS. 1 to 10 or a structure of the system on chip described with reference to FIGS. 11 to 15. The semiconductor system 500 may include an interconnect 501, a plurality of functional blocks 510, 515, 520, 525, 530, 540, 550, 560, 570 and 580, a first memory device 535, a display 545, a second memory device 555, and a camera 575.

In various embodiments, the semiconductor system 500 may be implemented as a PC or a mobile device. The mobile device may be implemented as a laptop computer, a mobile phone, a smart phone, a tablet personal computer (tablet), a personal digital assistant (PDA), an enterprise digital assistant (EDA), a digital still camera, a digital video camera, a portable multimedia player (PMP), a personal navigation device (PND) (or a portable navigation device), a handheld game console, a mobile Internet device (MID), a wearable computer, an Internet of Things (IoT) device, an Internet of Everything (IOE) device, a drone, or an e-book.

In various embodiments, the interconnect 501 and the plurality of functional blocks 510, 515, 520, 525, 530, 540, 550, 560, 570 and 580 may be implemented as system on chips. For example, the interconnect 501 and the plurality of functional blocks 510, 515, 520, 525, 530, 540, 550, 560, 570 and 580 may correspond to the semiconductor system 400 of FIG. 16.

In various embodiments, the functional block 410 shown in FIG. 16 may be any one of the plurality of functional blocks 510, 515, 520, 525, 530, 540, 550, 560, 570 and 580, the functional block 420 may be another one of the plurality of functional blocks 510, 515, 520, 525, 530, 540, 550, 560, 570 and 580, and each of the functional block 430 and the functional block 440 may be another one of the plurality of functional blocks 510, 515, 520, 525, 530, 540, 550, 560, 570 and 580.

In various embodiments, the CPU 510 may control the operation of each of the plurality of functional blocks 510, 515, 520, 525, 530, 540, 550, 560, 570 and 580 through the interconnect 501. For example, the interconnect 501 may be implemented as a bus. The communication module 515 may control data exchanged between an external communication device and the semiconductor system 500. For example, the communication module 515 may include a transceiver 515-1 for Bluetooth communication, a transceiver 515-2 for Wi-Fi communication and a GPS receiver 515-3 for receiving GPS signals. The data processed by the communication module 515 may be transmitted to at least one of the plurality of functional blocks 10, 515, 520, 525, 530, 540, 550, 560, 570 or 580 through the interconnect 501.

In various embodiments, the GPU 520 may process graphics data. The I/O interface 525 may transmit data input from a user to the interconnect 501 or transmit data transmitted from the interconnect 501 to an input and output device. The first memory controller 530 may write data in the first memory device 535 or read the data from the first memory device 535 under the control of the CPU 510 or the GPU 520. For example, the first memory device 535 may be a non-volatile memory device. The display controller 540 may control the operation of the display 545 under the control of the CPU 510 or the GPU 520. For example, the display controller 540 may transmit display data to the display 545.

In various embodiments, the second memory controller 550 may write data in the second memory device 555 or read the data from the second memory device 555 under the control of the CPU 510 or the GPU 520. For example, the second memory device 555 may be a volatile memory device.

In various embodiments, the USB controller 560 may transmit or receive data to or from a USB host. The camera controller 570 may process data output from the camera 575 and transmit the processed data to the interconnect 501. The debug controller 580 may control debugging of the semiconductor system 500.

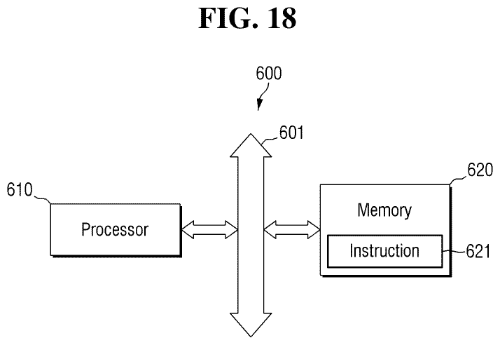

FIG. 18 is an exemplary view illustrating an electronic device according to some embodiments.

In various embodiments, the semiconductor device, such as the semiconductor integrated circuit of FIGS. 1 to 10 and the system on chip of FIGS. 11 to 15, may be fabricated by patterning one or more devices and their interconnection on a substrate, such as a semiconductor wafer. An electronic design automation (EDA) tool is software in which a designer positions various components of a circuit to act on each other and interconnects the components, and the semiconductor device may be fabricated through designing the integrated circuit using the EDA tool by the designer. The designer may generate a layout and a physical design of the semiconductor device by using the EDA tool, and then the semiconductor device may be fabricated based on the generated layout and physical design of the semiconductor device.

Referring to FIG. 18, an electronic device 600 may include a bus 601, a processor 610 and a memory 620. The electronic device 600 may be a fixed computing system such as a desktop computer, a workstation, or a server, or may be a portable computing system, such as a laptop computer. The processor 610 may be referred to as a processing unit, and may include, for example, at least one core capable of executing a command set (e.g., IA-32 (Intel Architecture-32), 64-bit extension IA-32, x86-64, PowerPC, Sparc, MIPS, ARM, IA-64, etc.), which may be a micro-processor, an application processor (AP), a digital signal processor (DSP), and a graphic processing unit (GPU).

In various embodiments, the designer of the semiconductor device may design the layout and the physical design of the semiconductor device by executing the EDA tool using the electronic device 600. The design of the semiconductor device using the EDA tool may be performed by the processor 610 accessing the memory 620 through the bus 601 and executing an instruction 621 stored in the memory 620. When the instruction 621 is executed by the processor 610, the instruction 621 may cause the processor 610 to design the layout and the physical design of the semiconductor device such as the semiconductor integrated circuit of FIGS. 1 to 10 or the system on chip of FIGS. 11 to 15.

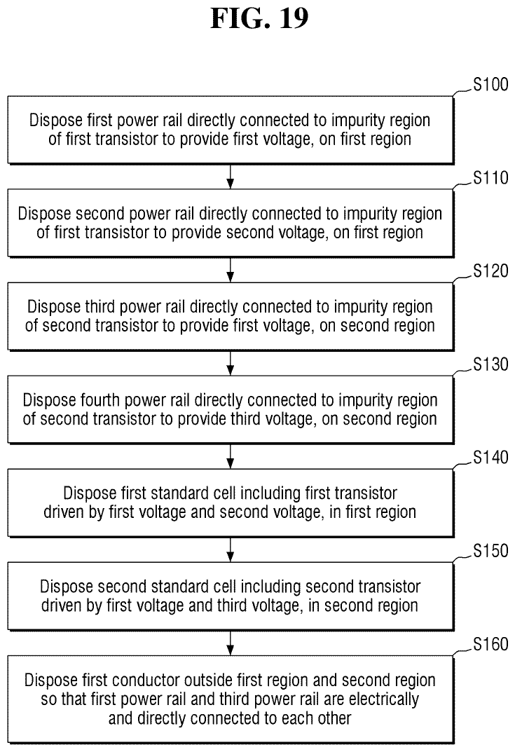

FIG. 19 is a flow chart illustrating an example of a method for designing a semiconductor integrated circuit or a system on chip according to some embodiments when the instruction of FIG. 18 is executed by the processor.

Referring to FIG. 19, a semiconductor substrate 110, which includes a region R1 and a region R2, which do not overlap each other, is provided. A power rail PR1 and a power rail PR2 may be disposed on the region R1 (S100 and S110). The power rail PR1 and the power rail PR2 may be directly connected to the impurity region of the transistor TR1 to provide a first voltage and a second voltage to the transistor TR1, respectively. A power rail PR3 and a power rail PR4 may be disposed on the region R2 (S120 and S130). The power rail PR3 and the power rail PR4 are directly connected to the impurity region of the transistor TR2 to provide a first voltage and a third voltage to the transistor TR2, respectively.

In various embodiments, a standard cell STD1 may be formed in the region R1 of the semiconductor substrate 110 (S140). The standard cell STD1 may include a transistor TR1, and the transistor TR1 may be directly connected to the power rail PR1 and the power rail PR2 through the impurity region, and may be driven by receiving the first voltage and the second voltage. The first voltage may be one of the high voltage VDD and the low voltage VSS of the transistor TR1, and the second voltage may be the other one of the high voltage VDD and the low voltage VSS of the transistor TR1.

In various embodiments, a standard cell STD2 may be formed in the region R2 of the semiconductor substrate 110 (S150). The region R2 may be a region that does not overlap the region R1. The standard cell STD2 may include a transistor TR2, and the transistor TR2 may be directly connected to the power rail PR3 and the power rail PR4 through the impurity region, and may be driven by receiving the first voltage and the third voltage. The first voltage may be one of the high voltage VDD and the low voltage VSS of the transistor TR2, and the third voltage may be the other one of the high voltage VDD and the low voltage VSS of the transistor TR2.

In various embodiments, one of the high voltage VDD and the low voltage VSS may be equally applied to the transistor TR1 disposed in the region R1 and the transistor TR2 disposed in the region R2. In other words, when the first voltage is the high voltage VDD of the transistor TR1 and the high voltage VDD of the transistor TR2, the electronic elements included in the region R1 and the region R2 may be driven by the same high voltage (the first voltage). Alternatively, when the first voltage is the low voltage VSS of the transistor TR1 and the low voltage VSS of the transistor TR2, the electronic elements included in the region R1 and the region R2 may be driven by the same low voltage (the first voltage).

Therefore, the power rail PR1 and the power rail PR3, which provide the same first voltage to the transistor TR1 and the transistor TR2, may be electrically and directly connected to each other using the conductor C1 (S160). At this time, the conductor C1 may be disposed on a region, in which a standard cell is not disposed, outside the region in which the standard cell STD1 is disposed and the region in which the standard cell STD2 is disposed, on the semiconductor substrate 110.

In various embodiments, after the power rails PR1 to PR4 are disposed and the standard cells STD1 and STD2 are disposed, the power rails for transmitting the same voltage may be electrically and directly connected to each other by using the conductor, but the embodiments are not limited thereto. For example, in some embodiments, when there are the power rails for transmitting the same voltage in the step of disposing the power rails PR1 to PR4 on the semiconductor substrate 110, the power rails for transmitting the same voltage may be electrically and directly connected to each other using the conductor even in a previous step of disposing the standard cells STD1 and STD2. In this way, when the semiconductor integrated circuit or the system on chip according to some embodiments is designed using the EDA tool, electrically and directly connecting the power rails for transmitting the same voltage by using the conductor is not limited to any step of the design, and the conductor may be additionally connected between the power rails in any step in which the power rails for transmitting the same voltage are found.

While the present disclosure has been particularly illustrated and described with reference to exemplary embodiments thereof, it will be understood by those of ordinary skill in the art that various changes in form and detail may be made therein without departing from the spirit and scope of the present disclosure as defined by the following claims. The exemplary embodiments should be considered in a descriptive sense only and not for purposes of limitation.

What is claimed is:

1. A semiconductor integrated circuit comprising:
a semiconductor substrate including a first region, in which a first transistor configured to be driven by a first voltage and a second voltage is disposed, and a second region, separate from the first region, in which a second transistor configured to be driven by a third voltage different from the first voltage and the second voltage is disposed;
a first power rail extending in a first direction on the first region, and directly connected to an impurity region of the first transistor to provide the first voltage;
a second power rail extending in the first direction on the first region and directly connected to the impurity region of the first transistor to provide the second voltage;
a third power rail extending in the first direction on the second region and directly connected to an impurity region of the second transistor to provide the first voltage;
a fourth power rail extending in the first direction on the second region and directly connected to the impurity region of the second transistor to provide the third voltage; and
a first conductor electrically and directly connecting the first power rail with the third power rail.

2. The semiconductor integrated circuit of claim 1, wherein the first conductor is at the same level as the first and third power rails and electrically connects the first power rail with the third power rail.

3. The semiconductor integrated circuit of claim 1, wherein the semiconductor substrate further includes a third region, in which a transistor is not disposed, between the first region and the second region, and
the first conductor is on the third region.

4. The semiconductor integrated circuit of claim 1, wherein the second power rail is spaced apart from the first power rail in a second direction intersecting with the first direction.

5. The semiconductor integrated circuit of claim 4, wherein each of the first power rail and the second power rail are provided as a plurality of power rails, and
each of the plurality of first power rails and each of the plurality of second power rails are alternately spaced apart from each other in the second direction.

6. The semiconductor integrated circuit of claim 1, wherein the first voltage is a ground voltage.

7. The semiconductor integrated circuit of claim 1, wherein the second voltage is a voltage having a magnitude smaller than that of the first voltage, and the third voltage is a voltage having a magnitude smaller than that of the first voltage.

8. The semiconductor integrated circuit of claim 1, further comprising a second conductor, which extends in a second direction intersecting with the first direction and is electrically connected to the first conductor.

9. The semiconductor integrated circuit of claim 8, wherein the first conductor and the second conductor are electrically connected to each other through a via extending along a direction intersecting a plane on which the semiconductor substrate is disposed.

10. The semiconductor integrated circuit of claim 1, wherein the first power rail is not aligned with the third power rail in the first direction, and
the first power rail is aligned with the fourth power rail in the first direction.

11. The semiconductor integrated circuit of claim 10, wherein the first conductor includes:
a first sub-conductor extending in the first direction and electrically connected to the first power rail;
a second sub-conductor extending in the first direction and electrically connected to the third power rail; and
a third sub-conductor extending in a second direction intersecting with the first direction, and electrically connecting the first sub-conductor with the second sub-conductor.

12. A system on chip comprising:
a semiconductor substrate including a first standard cell including a first transistor driven by a first voltage and a second voltage, a second standard cell including a second transistor driven by the first voltage and a third voltage, and a third standard cell including a third transistor driven by a fourth voltage and the second voltage;
a first power rail directly connected to an impurity region of the first transistor to provide the first voltage;
a second power rail directly connected to the impurity region of the first transistor to provide the second voltage;
a third power rail directly connected to an impurity region of the second transistor to provide the first voltage;
a fourth power rail directly connected to the impurity region of the second transistor to provide the third voltage;
a fifth power rail directly connected to an impurity region of the third transistor to provide the fourth voltage;
a sixth power rail directly connected to the impurity region of the third transistor to provide the second voltage;
a first conductor electrically and directly connecting the first power rail with the third power rail in a first region in which the first standard cell and the second standard cell of the semiconductor substrate are not disposed; and
a second conductor electrically and directly connecting the second power rail with the sixth power rail in a second region in which the first standard cell and the third standard cell of the semiconductor substrate are not disposed.

13. The system on chip of claim 12, wherein the first conductor is disposed at the same level as the first and third power rails to electrically connect the first power rail with the third power rail,
the second conductor is disposed at the same level as the second and sixth power rails to electrically connect the second power rail with the sixth power rail, and
the first conductor and the second conductor are disposed at the same level.

14. The system on chip of claim 13, wherein the first power rail and the third power rail extend in the first direction,
the system on chip further comprising a third conductor, which extending in a second direction intersecting with the first direction, and electrically connected to the first conductor, in the first region.

15. The system on chip of claim 14, wherein the second power rail and the sixth power rail extend in the first direction,
the system on chip further comprises a fourth conductor, extending in the second direction, and electrically connected to the second conductor in the second region.

16. The system on chip of claim 15, wherein the third conductor and the fourth conductor are disposed at the same level.

17. The system on chip of claim 12, wherein the first to sixth power rails extend in the first direction,
the first power rail is not aligned with the third power rail in the first direction,
the first power rail is aligned with the fourth power rail in the first direction,
the second power rail is not aligned with the sixth power rail in the first direction, and
the second power rail is aligned with the fifth power rail in the first direction.

18. The system on chip of claim 17, wherein the first conductor includes:
a first sub-conductor extending in the first direction and electrically connected to the first power rail;
a second sub-conductor extending in the first direction and electrically connected to the third power rail; and
a third sub-conductor extending in a second direction intersecting with the first direction, and electrically connecting the first sub-conductor with the second sub-conductor.

19. The system on chip of claim 18, wherein the second conductor includes:
a fourth sub-conductor extending in the first direction and electrically connected to the second power rail;
a fifth sub-conductor extending in the first direction and electrically connected to the sixth power rail; and
a sixth sub-conductor extending in the second direction, and electrically connecting the fourth sub-conductor with the fifth sub-conductor.

20. An electronic device comprising:
a processor; and
a memory configured to store an instruction,
wherein, when the instruction is executed by the processor, the instruction causes the processor:
to provide a semiconductor substrate, which includes a first region and a second region separate from the first region,
to form a first power rail extending in a first direction, and directly connected to an impurity region of a first transistor to provide a first voltage on the first region,
to form a second power rail extending in the first direction, and directly connected to the impurity region of the first transistor to provide a second voltage on the first region,
to form a third power rail extending in the first direction and directly connected to an impurity region of a second transistor to provide the first voltage, wherein the third power rail is on the second region,
to form a fourth power rail extending in the first direction and directly connected to the impurity region of the second transistor to provide a third voltage different from the second voltage on the second region,
to form a first standard cell including the first transistor driven by the first voltage and the second voltage in the first region,
to form a second standard cell including the second transistor driven by the first voltage and the third voltage in the second region, and
to form a first conductor outside the first region and the second region, so that the first power rail and the third power rail are electrically and directly connected to each other.
